(19) United States
(12) Patent Application Publication
(10) Pub. No.: US 2009/0251136 A1
(43) Pub. Date: Oct. 8, 2009

(54) ATTRACTION AND REPULSION OF MAGNETIC OF MAGNETIZABLE OBJECTS TO AND FROM A SENSOR SURFACE

(75) Inventors: Menno Willem Jose Prins, Rosmalen (NL); Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/373,740

(22) PCT Filed: Jun. 6, 2007
(86) PCT No.: PCT/IB07/52133

§ 371 Date: Jan. 14, 2009

(30) Foreign Application Priority Data
Jul. 17, 2006 (EP) 06117291.2

(51) Int. Cl. G01R 33/12; H01H 47/00

(52) U.S. Cl. 324/228; 361/143

(57) ABSTRACT

The present invention provides a magnetic sensor device a first magnetic field generating means (21a, 21b) for attracting magnetic or magnetizable objects (22), e.g. magnetic particles, to a sensor surface (23) and a second magnetic field generating means (25) for, in combination with the first magnetic field, repelling magnetic or magnetizable objects (22), e.g. magnetic particles, from the sensor surface (23). The magnetic fields generated by the first and second magnetic field generating means have substantially anti-parallel directions. The present invention furthermore provides a method for attracting and repelling magnetic or magnetizable objects (22), e.g. magnetic particles, to and from a sensor surface (23).

### FIELD OF THE INVENTION

The present invention relates to sensing systems and magnetic sensor devices. More particularly the present invention relates to attraction and repulsion of magnetic or magnetizable particulate objects such as magnetic nanoparticles to and from a sensor surface. The present invention furthermore provides a method for attracting and repelling magnetic or magnetizable particulate objects, e.g. magnetic particles, to and from a sensor surface. The method and device according to the present invention may be used amongst others in biological or chemical sample analysis.

### BACKGROUND OF THE INVENTION

Magnetic sensors based on AMR (anisotropic magneto resistance), GMR (giant magneto resistance) and TMR (tunnel magneto resistance) elements or on Hall sensors, are nowadays gaining importance. Besides the known high-speed applications such as magnetic hard disk heads and MRAM, new relatively low bandwidth applications appear in the field of molecular diagnostics (MDx), current sensing in IC's, automotive, etc.

The introduction of micro-arrays or biochips comprising such magnetic sensors is revolutionizing the analysis of biomolecules such as DNA (desoxyribonucleic acid), RNA (ribonucleic acid) and proteins. Applications are, for example, human genotyping (e.g. in hospitals or by individual doctors or nurses), bacteriological screening, biological and pharmacological research. Such magnetic biochips have promising properties for, for example, biological or chemical sample analysis, in terms of sensitivity, specificity, integration, ease of use and costs.

Biochips, also called biosensor chips, biological microchips, gene-chips or DNA chips, consist in their simplest form of a substrate on which a large number of different probe molecules are attached, on well defined regions on the chip, to which molecules or molecule fragments that are to be analyzed can bind if they are perfectly matched. For example, a fragment of a DNA molecule binds to one unique complementary DNA (c-DNA) molecular fragment. The occurrence of a binding reaction can be detected, for example by using markers, e.g. fluorescent markers or magnetic labels, that are coupled to the molecules to be analyzed. This provides the ability to analyze small amounts of a large number of different molecules or molecular fragments in parallel, in a short time.

In a biosensor an assay takes place. Assays generally involve several fluid actuation steps, i.e. steps in which materials are brought into movement. Examples of such steps are mixing (e.g. for dilution, or for the dissolution of labels or other reagents into the sample fluid, or labeling, or affinity binding) or the refresh of fluid near to a reaction surface in order to avoid that diffusion becomes rate-limiting for the reaction. Preferably the actuation method should be effective, reliable and cheap.

In order to increase the probability and specificity of binding magnetic particles to a sensor surface, the magnetic particles may successively be attracted to and repelled from the sensor surface. According to prior art devices, this is done by applying an external magnetic field gradient in the z-direction, i.e. in a direction substantially perpendicular to the surface of the sensor device.

A drawback thereof is that the magnetic forces are present over the total sensor area at the same time, which does not allow detailed spatial control of the field. This may lead to difficulties e.g. in multiplexing different assays on a same chip.

A further drawback is that switching off the gradient involves a change of field in a large volume and thereby a large energy dissipation.

Furthermore, in a biosensor, it may be important to distinguish weak biomolecular bonds from strong biomolecular bonds. Even more interesting, it may be preferred to perform a population analysis, i.e. quantitatively distinguishing molecules in terms of their concentration and their binding affinity/avidity. This may, for example, be applied in the analysis of pools of antibodies in food and in medical diagnostics.

Traditionally, a distinction between strong and weak bonds is made by a washing step, but in this way it is difficult to do a population analysis and it requires careful fluid handling steps. For an integrated biosensor, the use of magnetic forces to make this distinction is more beneficial.

In a presently known sensor geometry, magnetic particles 5 are attracted to a sensor surface 4 due to an excitation field generated by field generating wires during detection. This is illustrated in FIG. 1. The sensor device illustrated in FIG. 1 comprises a first and second field generating wire 1, 2 and a sensor element 3 in between the field generating wires 1, 2.

By applying a current to at least one of the field generating wires 1, 2, an internal magnetic field is generated. FIG. 2 shows the internal magnetic field Hᵢₙₜ(x) in the x-direction (axes oriented as illustrated in FIG. 1), i.e. the direction parallel to the surface and perpendicular to the in the z-direction at 0.85 μm, i.e. at the sensor surface 4 (see FIG. 1), and generated by sending an excitation current of 15 mA through the first field generating wire 1. Curve 7 shows the internal magnetic field in the x-direction and curve 8 shows the internal magnetic field in the z-direction. It has to be noted that in all figures the lower left corner of the first field generating wire 1 forms the origin of the co-ordinate system indicated in the Figures.

The magnetic force exerted by the generated magnetic field on a magnetic nanoparticle 5, such as e.g. a super paramagnetic bead, can be given by:

\vec{F}_{magn}=−∇u=∇(\vec{m}·\vec{B})=(\vec{m}·∇)\vec{B} (1)

with \vec{m} the magnetic moment of the magnetic particle 5 and \vec{B} the applied magnetic field. When an external magnetic field is applied to the configuration illustrated in FIG. 1, the magnetic particle 5 is magnetized by the external field \vec{H}ₑₓₜ and by the internal field Hᵢₙₜ generated by sending current through the field generating wire 1. Hence:

\vec{F}_{magn}=μ₀χ_{bead}{(\vec{H}ₑₓₜ+\vec{H}ᵢₙₜ)·∇(\vec{H}ₑₓₜ+\vec{H}ᵢₙₜ)} (2)

In case of, for example, 300 nm Ademtech superparamagnetic beads, χ_{bead}=4.22·10⁻²⁰ and μ₀=4π·10⁻⁷.

In case \vec{H}ₑₓₜ is homogeneous this formula reduces to

\vec{F}_{magn}=μ₀χ_{bead}{(\vec{H}ₑₓₜ+\vec{H}ᵢₙₜ)·∇(\vec{H}ᵢₙₜ)} (3)

By dissolving the magnetic force in x and z components,

$$\begin{matrix}{F}_{magn , x} = {μ}_{0} {χ}_{bead} \{ \begin{matrix}( {H}_{ext , x} + {H}_{int , x} ) \frac{\partial {H}_{int , x}}{\partial x} + \\ ( {H}_{ext , z} + {H}_{int , z} ) \frac{\partial {H}_{int , x}}{\partial z}\end{matrix} \} & ( 4 ) \\ {F}_{magn , z} = {μ}_{0} {χ}_{bead} \{ \begin{matrix}( {H}_{ext , x} + {H}_{int , x} ) \frac{\partial {H}_{int , z}}{\partial x} + \\ ( {H}_{ext , z} + {H}_{int , z} ) \frac{\partial {H}_{int , z}}{\partial z}\end{matrix} \} & ( 5 )\end{matrix}$$

it becomes clear that magnetic particles 5 present above the first field generating wire 1 are attracted towards the wire 1. This is illustrated by the arrow with reference number 6 in FIG. 1 and in FIGS. 3 and 4, which respectively show horizontal and vertical magnetic forces at the chip surface 4 as a function of the x-position of the magnetic particle 5 at z=0.85 μm (see FIG. 1), i.e. at the sensor surface, for an excitation current of 15 mA through field generating wire 1 and for 300 nm Ademtech superparamagnetic beads.

As a variation, both field generating wires 1 and 2 may be simultaneously activated, as illustrated in FIG. 5. As a result, magnetic particles 5 are pulled away from the center of the sensor and attracted towards the wires 1 and 2. This phenomenon may be interpreted as a form of repulsion or as a repelling force, indicated by reference number 9 in FIG. 5. This is illustrated in FIGS. 6 and 7 in which respectively horizontal and vertical magnetic forces at the chip surface 4 are illustrated as a function of the x-position of the magnetic particle 5 at z=0.85 μm, i.e. at the sensor surface, for 300 nm Ademtech beads and for an excitation current of 15 μm through the field generating wires 1 and 2. From FIG. 7 it can be seen that the repelling force is located above the sensor element 3 and is very small, i.e. smaller than 1 fN.

With on-chip current wires 1, 2, as described above, field gradients can be locally applied, multiplexing by addressing the sensors individually is easy and high gradients can be generated. However, a disadvantage of on-chip current wires 1, 2 is that the field gradient is directed toward the chip surface 4 (see, for example, Panhorst, Biosens. Bioelectron., vol. 20, p. 1685 (2005), p 1685). This means that magnetic particles 5 are attracted toward or along the chip surface 4, which gives an ill-defined force on the biomolecular bond between the magnetic particle 5 and the chip surface 4, when measuring the bond strength during measurements.

For discriminating between specific and non-specific bonds, typically a force of about 100 fN is required. As already said, from FIG. 7 it can be seen that the vertical repelling force in the standard geometry is smaller than 1 fN and thus is way too low to be able to remove magnetic particles 5 from the sensor surface 4.

### SUMMARY OF THE INVENTION

It is an object of the present invention to provide a good magnetic sensor device and a good method for attracting and repelling magnetic or magnetizable objects to and from a sensor surface.

The above objective is accomplished by a method and device according to the present invention.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect, the present invention provides a magnetic sensor device. The magnetic sensor device has a surface and comprises:

a first integrated magnetic field generating means for generating a first magnetic field in a first direction and having a first magnetic field strength, the first magnetic field being for attracting magnetic or magnetizable objects to the surface of the magnetic sensor device,

at least one sensor element,

a second magnetic field generating means for generating a second magnetic field in

a second direction and having a second magnetic field strength, the second magnetic field, in combination with the first magnetic field, being for repelling magnetic or magnetizable objects having a binding strength below a predetermined value from the surface of the magnetic sensor device, the first and second direction being substantially anti-parallel to each other, and

driving means for controlling modulation of the first and second magnetic field strength.

With substantially anti-parallel is meant that the first direction of the first magnetic field and the second direction of the second magnetic field enclose an angle of less than 10°, preferably less than 5° and most preferred less than 1°.

An advantage of the device according to embodiments of the present invention is that the anti-parallel orientation of the first and second magnetic field creates a field minimum above the first magnetic field generating means. Therefore, the field gradient is oriented away from the first magnetic field generating means. A magnetic or magnetizable object, e.g. magnetic particle, located in the sample fluid in the vicinity of the first magnetic field generating means experiences a force away from the sensor surface and is pulled into the fluid and thus is repelled from the sensor surface after being attracted to it.

According to embodiments of the invention, the driving means for controlling modulation of the first and second magnetic field strength may be driving means for controlling switching on and switching off of the first integrated magnetic field generating means and the second magnetic field generating means.

According to embodiments of the invention, the second magnetic field generating means may comprise an external magnetic field generating means.

According to embodiments of the invention, the second magnetic field generating means may comprise at least an integrated magnetic field generating means.

The magnetic sensor device may be formed in a substrate and, according to embodiments of the invention, the at least one sensor element may be integrated in the sensor substrate. However, according to other embodiments of the invention, it is also possible that the at least one sensor element may not be integrated in the sensor substrate and that it may be partially or fully embedded in a sensor reader. As one example, the at least one sensor element may be a magnetoresistive sensor element that is embedded in the substrate. As another example, the at least one sensor element may be an optical imaging system that is embedded in the instrument for sensor readout.

The second magnetic field generating means may, according to embodiments of the invention, comprise an external magnetic field generating means and at least one integrated magnetic field generating means.

The at least one sensor element and the first integrated magnetic field generating means may extend in a first direction and the at least one integrated magnetic field generating means of the second magnetic field generating means may be oriented in a second direction substantially perpendicular to the first direction.

An advantage hereof is that a rather large external magnetic field may be applied without the sensor device going into saturation.

According to other embodiments of the invention, the second magnetic field generating means may comprise an external magnetic field generating means and the first magnetic field generating means may be formed by an integrated magnetic field generating means oriented in a direction substantially perpendicular to the direction in which the at least one sensor element is oriented. According to further embodiments, the magnetic sensor device may furthermore comprise a third magnetic field generating means for generating a third magnetic field for orienting magnetic moments of the magnetic or magnetizable objects in a sensitive direction of the sensor element, which in these embodiments may be a magnetic sensor element, such that presence of magnetic or magnetizable objects and amount of magnetic or magnetizable objects present may be detected and measured. Hence, according to these embodiments, there may be three magnetic fields, i.e. a first magnetic field generated by the integrated magnetic field generating means for attracting magnetic or magnetizable objects to the sensor surface and, a second magnetic field generated by the external magnetic field generating means which, in combination with the first magnetic field, generates a repelling force on the magnetic or magnetizable objects, and a third magnetic field generated by the third magnetic field generating means and oriented substantially parallel to the sensor element for excitation of the magnetic or magnetizable objects for detection. Each individual field produces an attracting force when activated solely.

The at least one integrated magnetic field generating means may be a current wire.

The external magnetic field generating means may be a permanent magnet. The generated external magnetic field may have a magnitude in the range of between 200 A/m and 20000 A/m.

According to embodiments of the invention, the at least one integrated magnetic field generating means of the second magnetic field generating means may be oriented in a direction substantially parallel to the first integrated magnetic field generating means and to the at least one sensor element.

An advantage of these embodiments is that no external magnetic field is required for repelling the magnetic or magnetizable objects, e.g. magnetic particles, from the sensor surface.

The second magnetic field generating means may comprise a plurality of current wires. An advantage thereof is that no high currents are required and thus less heat dissipation occurs.

The at least one integrated magnetic field generating means of the second magnetic field generating means may located in between the sensor surface and the first integrated magnetic field generating means. An advantage thereof is that, in that way, the at least one integrated magnetic field generating means of the second magnetic field generating means does not disturb the geometry of the sensor device too much.

The first magnetic field generating means may comprise at least one current wire.

The at least one sensor element may be one of a GMR sensor element, a TMR sensor element, an AMR sensor element, a Hall sensor, . . . .

In a second aspect, the present invention also provides a biochip comprising at least one magnetic sensor device according to embodiments of the present invention.

The present invention also provides the use of the magnetic sensor device according to embodiments of the invention in biological or chemical sample analysis.

The present invention also provides the use of the biochip according to embodiments of the invention in biological or chemical sample analysis.

In a third aspect, the present invention provides a method for attracting and repelling magnetic or magnetizable objects from a sensor surface of a sensor device. The method comprises:

modulating a first magnetic field strength of a first magnetic field generated by a first magnetic field generating means, the first magnetic field being for attracting magnetic or magnetizable objects to the sensor surface, at least some of the attracted magnetic or magnetizable objects hereby being given a possibility to bind to the sensor surface, and

modulating a second field strength of a second magnetic field generated by a second magnetic field generating means, the second magnetic field in combination with the first magnetic field, being for repelling from the sensor surface magnetic or magnetizable objects having a bonding strength below a predetermined value,

wherein the first and second magnetic field are generated such that the first magnetic field has a first direction and the second magnetic field has a second direction, the first and second direction being substantially anti-parallel to each other.

With substantially anti-parallel is meant that the direction of the first magnetic field and the direction of the second magnetic field enclose an angle of less than 10°, preferably less than 5° and most preferred less than 1°.

An advantage of the device according to embodiments of the present invention is that the anti-parallel orientation of the first and second magnetic field creates a field minimum above the first magnetic field generating means. Therefore, the field gradient is oriented away from the first magnetic field generating means. A magnetic or magnetizable object, e.g. magnetic particle, located in the sample fluid in the vicinity of the first magnetic field generating means experiences a force away from the sensor surface and is pulled into the fluid and thus is repelled from the sensor surface after being attracted to it.

According to embodiments of the invention, modulating the first and second magnetic field strength may be performed by:

switching on the first integrated magnetic field generating means for generating a first magnetic field for attracting magnetic or magnetizable objects to the sensor surface, and

switching on the second magnetic field generating means for generating a second magnetic field for, in combination with the first magnetic field, repelling from the sensor surface magnetic or magnetizable objects having a bonding strength below a predetermined value.

The present invention also provides the use of the method according to embodiments of the present invention in biological or chemical sample analysis.

The present invention also provides the use of the method according to embodiments of the present invention for determining the binding strength of magnetic or magnetizable objects to a sensor surface.

The present invention also provides the use of the method according to embodiments of the present invention for distinguishing between specific and non-specific bonds of magnetic or magnetizable objects to a sensor surface.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 shows a magnetoresistive sensor according to the prior art.

FIG. 2 illustrates the internal magnetic field at the sensor surface of the sensor of FIG. 1 at z=0.85 μm and for an excitation current of 15 mA.

FIGS. 3 and 4 respectively illustrate horizontal and vertical magnetic forces at the sensor surface of the sensor of FIG. 1 at z=0.85 μm and for an excitation current of 15 mA.

FIG. 5 shows a magnetoresistive sensor according to the prior art.

FIGS. 6 and 7 respectively illustrate horizontal and vertical magnetic forces at the sensor surface of the sensor of FIG. 5 at z=0.85 μm and for an excitation current of 15 mA.

FIG. 8 shows a magnetoresistive sensor according to a first embodiment of the invention using an external magnetic field for repelling magnetic particles from the sensor surface.

FIG. 9 shows the internal magnetic field at the sensor surface at z=0.85 μm an with an excitation current of 6 mA for the sensor device of FIG. 8.

FIGS. 10 and 11 respectively illustrate horizontal and vertical magnetic forces at the sensor surface of the sensor of FIG. 8 at z=0.85 μm and for an excitation current of 15 mA.

FIG. 12 and FIG. 13 respectively illustrate horizontal and vertical magnetic forces at the sensor surface of the sensor of FIG. 5 at z=0.85 μm, for an excitation current of 12 mA and for an external magnetic field of −10 kA/m.

FIG. 14 shows a magnetic sensor device according to a second embodiment of the present invention.

FIGS. 15 and 16 show examples of a sensor device according to a third embodiment of the present invention.

FIG. 17 shows a magnetic sensor device according to a fourth embodiment of the present invention.

FIGS. 18 and 19 respectively show horizontal and vertical magnetic forces at the sensor surface of the sensor of FIG. 15 at z=0.85 μm.

FIG. 20 shows a sensor device according to a fifth embodiment of the present invention.

FIGS. 21 and 22 respectively show horizontal and vertical magnetic forces at the sensor surface of the sensor of FIG. 20 at z=0.85 μm.

FIG. 23 illustrates a biochip comprising magnetic sensor devices according to embodiments of the present invention.

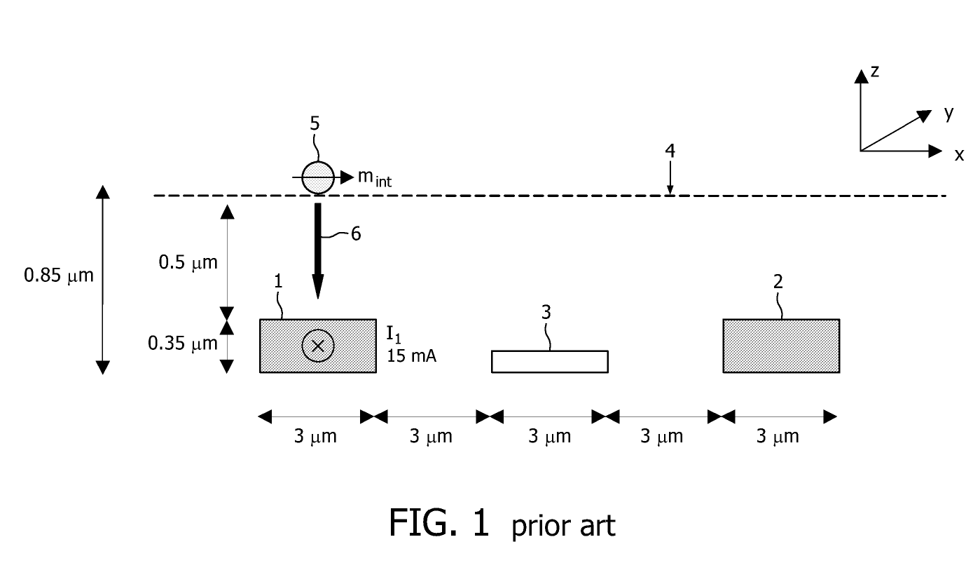

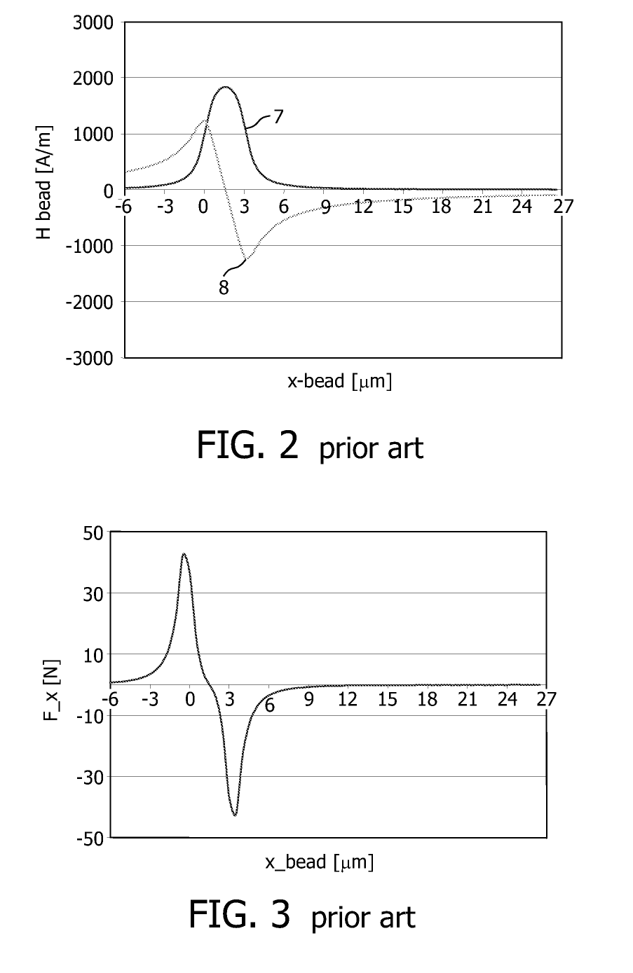

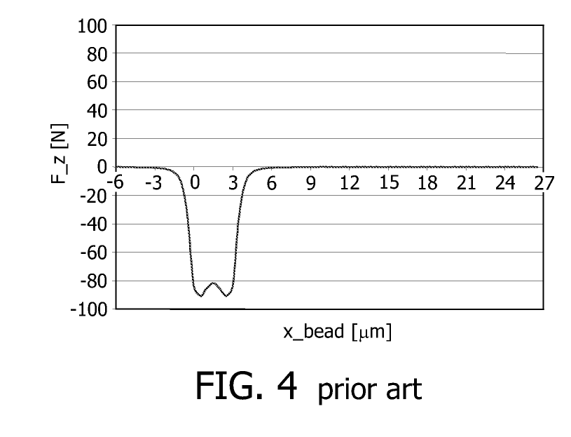

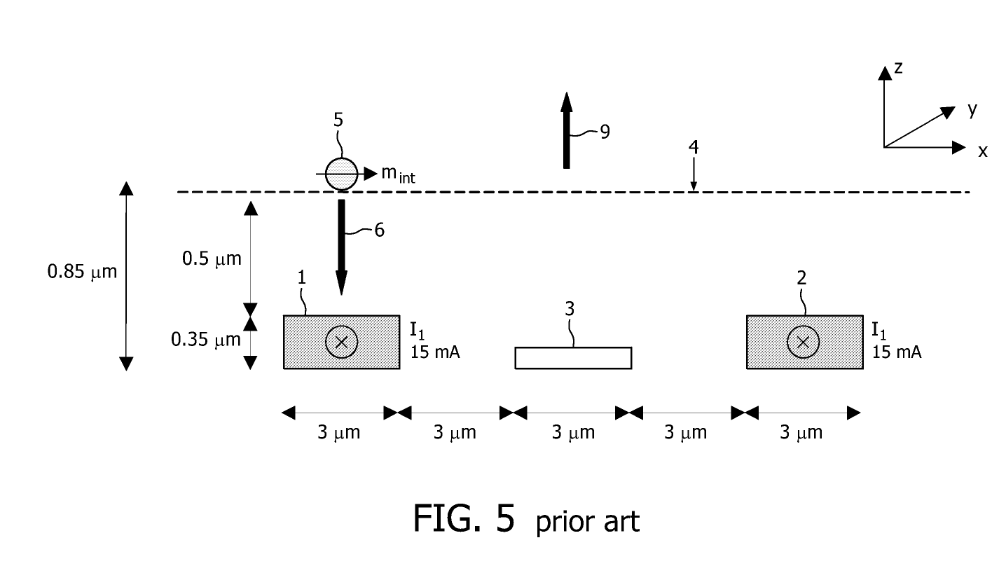

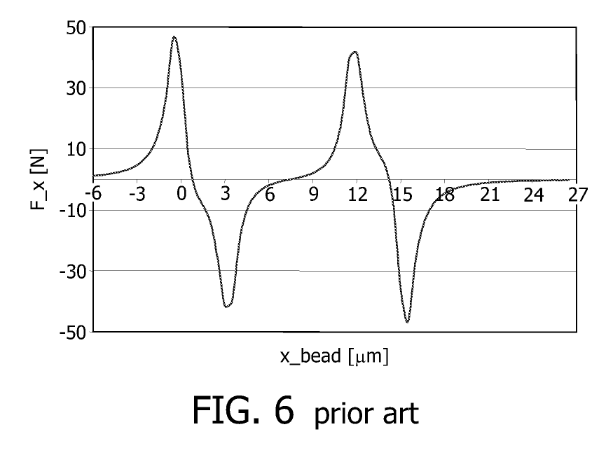

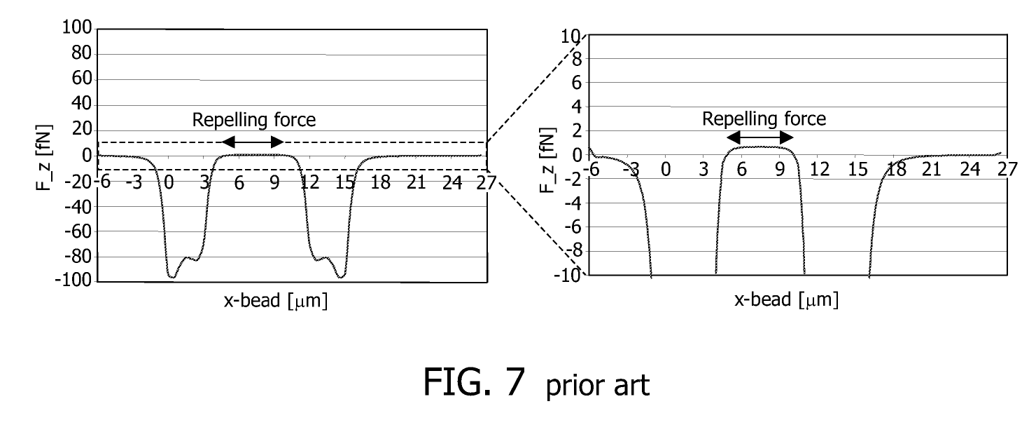

In the different Figures, the same reference signs refer to the same or analogous elements.

### DETAILED DESCRIPTION OF EMBODIMENTS

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

The present invention provides a magnetic sensor device comprising a first integrated magnetic field generating means for generating a first magnetic field in a first direction, the first magnetic field being for attracting magnetic or magnetizable objects to a surface of the magnetic sensor device where they can bind to binding sites, at least one sensor element, and a second magnetic field generating means for generating a second magnetic field in a second direction, the second magnetic field, in combination with the first magnetic field, being for repelling magnetic or magnetizable objects having a binding strength below a predetermined value from the surface of the magnetic sensor device. According to the present invention, the first and second magnetic fields are oriented substantially anti-parallel and in the xy-plane, i.e. in a horizontal direction (see further in the drawings), or in other words in a direction substantially parallel to the plane of the sensor surface, hereby generating a vertical repelling force or in other words a repelling force in the z-direction, i.e. when the sensor surface is lying in an xy-plane, a repelling force in a direction substantially perpendicular to the plane of the sensor surface and away from the sensor surface. Hence, according to the present invention, the generated magnetic fields may be homogeneous or may be non-homogeneous. The latter is mostly the case, especially when the magnetic fields are generated by integrated magnetic field generating means such as current wires.

With substantially anti-parallel is meant that the first and second direction may be not exactly opposite to each other but may include an angle of less than 10°, preferably less than 5° and most preferred less than 1°.

According to embodiments of the invention, the second magnetic field generating means may comprise an external magnetic field generating means.

According to more preferred embodiments of the present invention, the second magnetic field generating means may comprise at least an integrated magnetic field generating means.

A combination of external magnetic field generating means and integrated magnetic field generating means may be provided for the second magnetic field generating means.

The present invention furthermore provides a method for attracting and repelling magnetic or magnetizable particulate objects, e.g. magnetic particles, to and from a sensor surface.

The magnetic sensor device and the method according to the present invention can, for example, be used for distinguishing between strong and weak bonds between magnetic or magnetizable objects, e.g. magnetic particles, and a sensor surface or between specific and non-specific bonds of magnetic or magnetizable objects, e.g. magnetic particles, on a sensor surface. Furthermore, the magnetic sensor device may be used for determining binding strength of magnetic or magnetizable objects, e.g. magnetic particles, to a sensor surface. The device and method according to the present invention may also be used for attracting and repelling magnetic or magnetizable objects during detecting and/or quantifying measurements of target molecules in a sample fluid. The magnetic or magnetizable objects, e.g. magnetic particles, may be used as a label for target molecules to be detected. Hence, the magnetic sensor device according to the present invention may combine in one sensor device the detection of magnetic or magnetizable objects, e.g. magnetic particles, bound to the sensor surface and, for example, the determination of the strength of the bond between the magnetic or magnetizable object, e.g. magnetic nanoparticle, and the sensor surface.

The surface of the sensor device may be modified by a coating which is designed to attract certain molecules or may be modified by attaching molecules to it, which are suitable to bind the target molecules which are present in the sample fluid. Such molecules are know to the skilled person and include complementary DNA, antibodies, antisense RNA, etc. Such molecules may be attached to the surface by means of spacer or linker molecules. The surface of the sensor device can also be provided with molecules in the form of organisms (e.g. viruses or cells) or fractions of organisms (e.g. tissue fractions, cell fractions, membranes). The surface of biological binding can be in direct contact with the sensor chip, but there can also be a gap between the binding surface and the sensor chip. For example, the binding surface can be a material that is separated from the chip, e.g. a porous material. Such a material can be a lateral-flow or a flow-through material, e.g. comprising microchannels in silicon, glass, plastic, etc. The binding surface can be parallel to the surface of the sensor chip. Alternatively, the binding surface can be under an angle with respect to, e.g. perpendicular to, the surface of the sensor chip.

The present invention will further be described by means of a magnetic sensor device based on GMR elements. However, this is not limiting the invention in any way. The present invention may be applied to sensor devices comprising any sensor element suitable for detecting the presence or determining the amount of magnetic or magnetic or magnetizable objects, e.g. magnetic nanoparticles, on or near a sensor surface based on any property of the particles. For example, detection of the nanoparticles may be done by any suitable means, e.g. magnetic methods (magnetoresistive sensor elements, hall sensors, coils), optical methods (e.g. imaging fluorescence, chemiluminescence, absorption, scattering, surface plasmon resonance, Raman, . . . ), sonic detection methods (e.g. surface acoustic wave, bulk acoustic wave, cantilever, quartz crystal, . . . ), electrical detection methods (e.g. conduction, impedance, amperometric, redox cycling),etc.

The sensor element may be integrated in the sensor substrate, or may be partially or fully embedded in a sensor reader. As one example, the sensor element may be a magnetoresistive sensor element that is embedded in the substrate. As another example, the sensor element may be an optical imaging system that is embedded in an instrument for sensor readout.

Furthermore, the present invention will be described by means of the magnetic or magnetizable objects being magnetic particles. The term magnetic particles is to be interpreted broadly such as to include any type of magnetic particles, e.g. ferromagnetic, paramagnetic, superparamagnetic, etc. as well as particles in any form, e.g. magnetic spheres, magnetic rods, a string of magnetic particles, or a composite particle, e.g. a particle containing magnetic as well as optically-active material, or magnetic material inside a non-magnetic matrix. Preferably, the magnetic or magnetizable objects may be ferromagnetic particles which contain small ferromagnetic grains with a fast magnetic relaxation time and which have a low risk of clustering. Again, the wording used is only for the ease of explanation and does not limit the invention in any way.

According to a first embodiment of the invention, a magnetic sensor device 20 is provided which comprises a second magnetic field generating means formed by an external magnetic field generating means. The external magnetic field generating means may be used to put the binding of magnetic particles 22 to a sensor surface 23 under stringency.

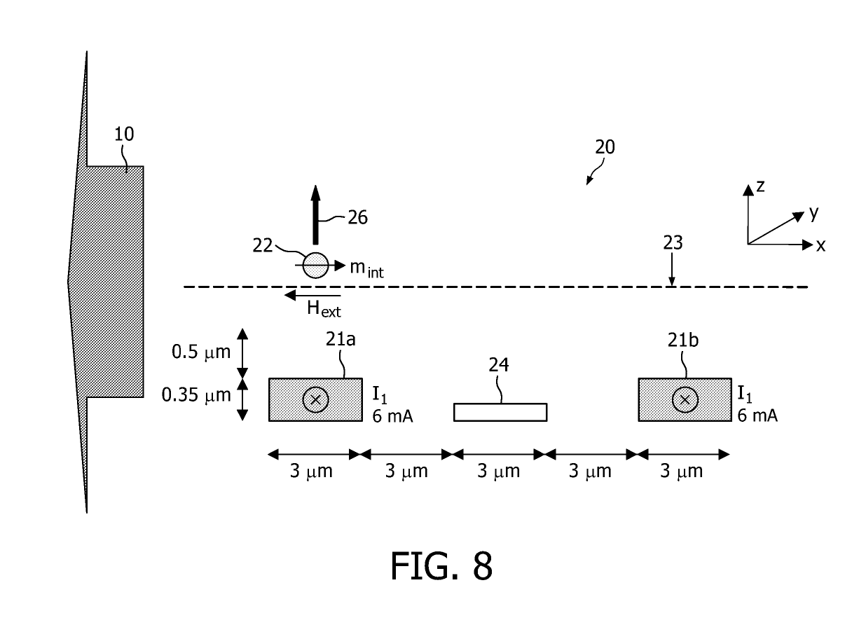

FIG. 8 illustrates a magnetic sensor device 20 which uses an external magnet, in combination with an integrated magnetic field generating means 21a, 21b, for repelling the magnetic particles 22 from the sensor surface 23. Therefore, the magnetic sensor device 20 according to the first embodiment comprises a first magnetic field generating means 21a, 21b for generating a first magnetic field for attracting magnetic particles 22 to the sensor surface 23. The first magnetic field generating means 21a, 21b is integrated in the sensor device 20. According to the example given in FIG. 8, the first integrated magnetic field generating means 21a, 21b may comprise a first and second current wire 21a, 21b respectively. This example is not limiting the invention, the first integrated magnetic field generating means may also comprise only one current wire or may comprise more than two current wires. The invention will further be described by means of the first integrated magnetic field generating means comprising first and second current wires 21a, 21b but this is not intended to limit the invention.

By the combination of an almost homogeneous external magnetic field along the negative x-as (indicated by reference number 10) generated by an external magnetic field generating means and an on-chip generated magnetic field generated by the integrated magnetic field generating means 21a, 21b and oriented in a direction substantially anti-parallel to the direction of the external magnetic field, magnetic particles 22 may be repelled (indicated by reference number 26) from the sensor surface 23.

In order to achieve effective repulsion in the positive z-direction, the relation

$$\frac{{H}_{ext , x}}{{H}_{int , x}} \leq - 1$$

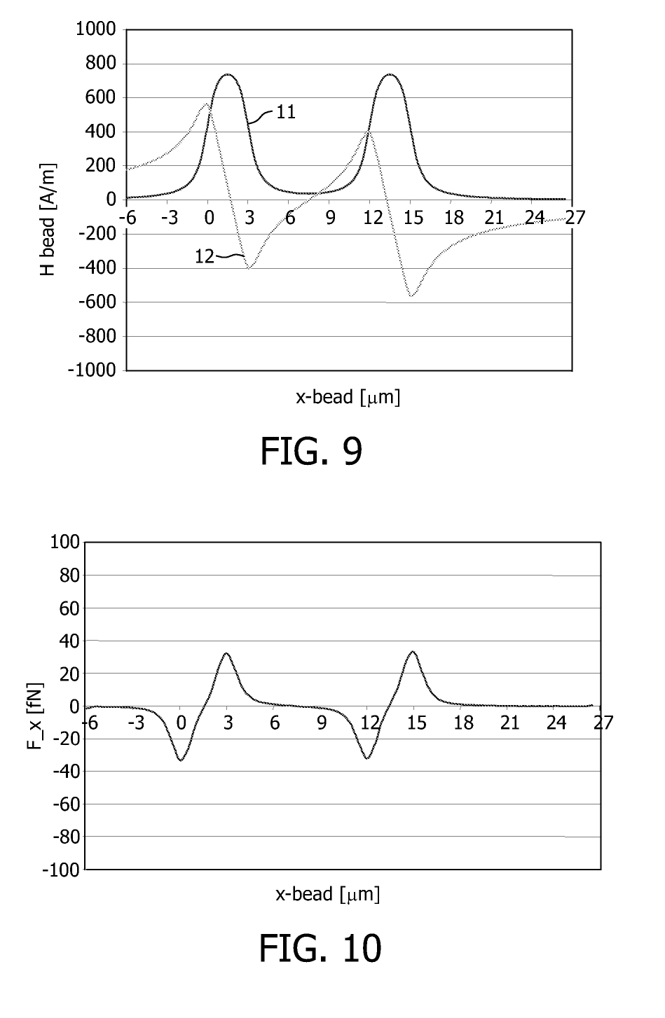

must hold. To repulse during magnetic measurements this ratio is limited by the dynamic range of the sensor (8 kA/m). Hence, the allowed magnetic field magnitude |Hₓ|≦2000 A/m. As a result the maximum excitation current for exciting the current wires 21a, 21b is limited to 6 mA. FIG. 9 illustrates the resulting on-chip magnetic field for the two wires 21a, 21b. Curve 11 illustrates the on-chip generated magnetic field in the x-direction, curve 12 illustrates the on-chip generated magnetic field in the z-direction.

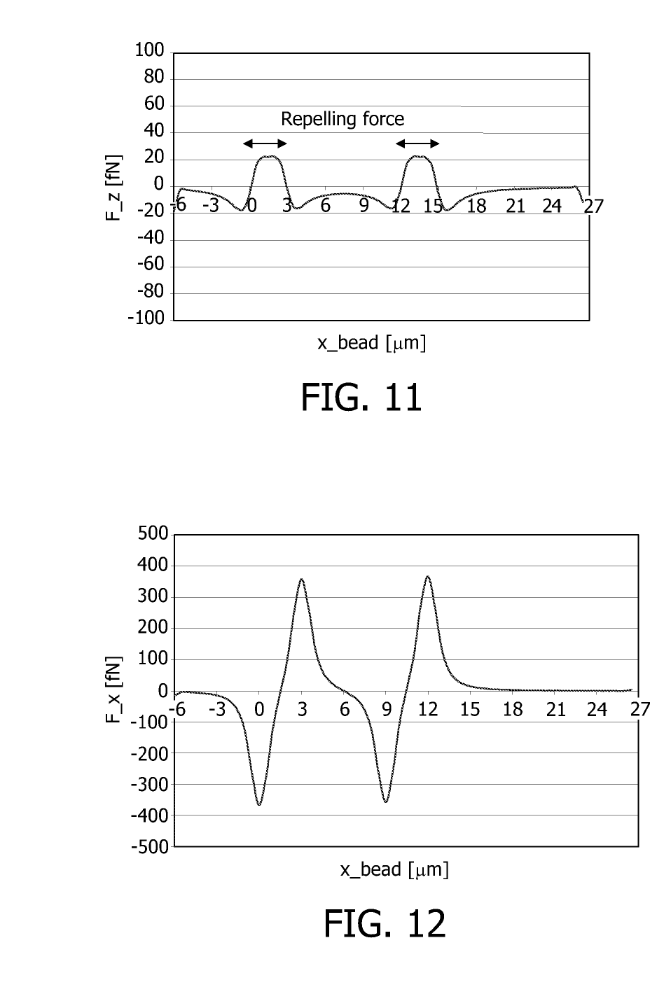

In FIGS. 10 and 11 respectively show the horizontal and vertical magnetic forces at the sensor surface 23 as a function of the x-position of the magnetic particles 22 at z=0.85 μm, for an excitation current of 6 mA, H_{ext,x}=−2000 A/m and for 300 nm Ademtech beads. It can be seen from these figures that, under the above-described conditions, the repulsion force is rather small, i.e. in the example given about 20 fN which is much smaller than the 100 fN required to remove non-specific bindings from the sensor surface 23.

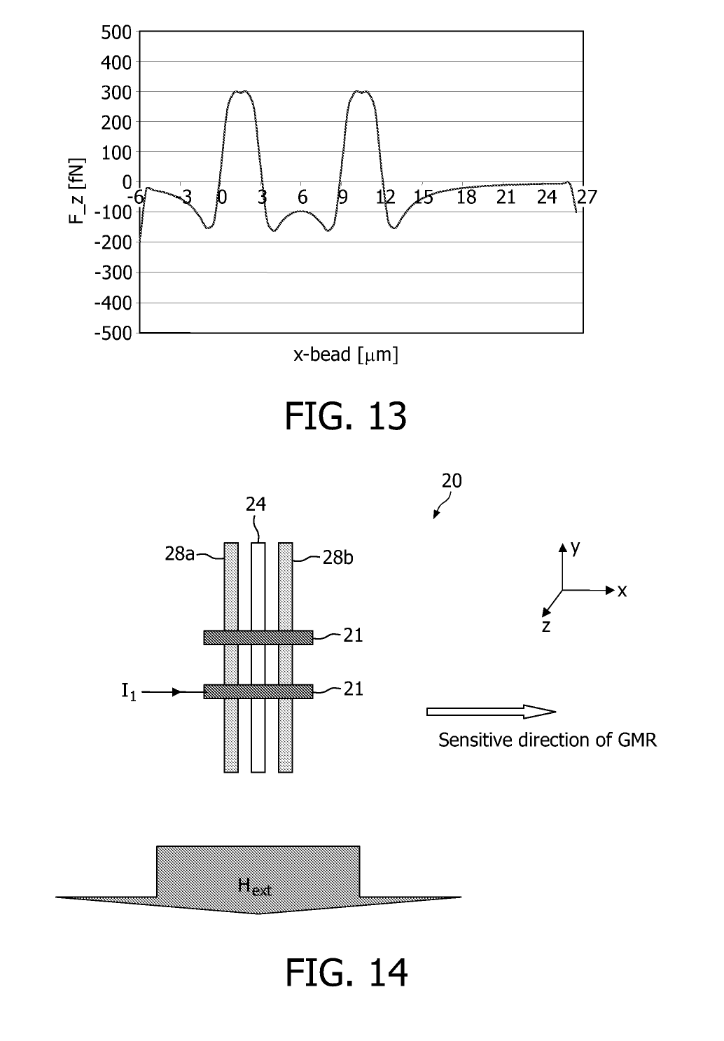

To overcome this problem, a larger external field can be applied, e.g. 10 kA/m. In this case, however, no accurate measurements for determining the presence or amount of magnetic particles 22 are possible during repelling because the sensor element 24 will be at least partly saturated due the higher external field. FIGS. 12 and 13 respectively show horizontal and vertical magnetic forces at a sensor surface 23 as a function of the x-position of the magnetic particles at z=0.85 μm, for an excitation current of 12 mA, an external magnetic field of 10 kA/m along the negative x-axis and for 300 nm Ademtech beads. It can be seen that the repelling force is concentrated above the excitation wires 21a, 21b which is the region where magnetic particles 22 are concentrated during detection when the external field is switched off, and that the repelling force is larger than 100 fN.

As already described before, when applying an external magnetic field to a magnetic sensor as described in the first embodiment and as illustrated in FIG. 8, only a low repulsion or repelling force may be obtained, which may not be enough to repel some magnetic particles 22 from the sensor surface, depending on the particles and the binding strength. This is because the applied external magnetic field may not be too high because otherwise, when it is desired to repel magnetic nanoparticles from the sensor surface while measurements are performed, the magnetic sensor would go into saturation. Hence, no accurate detection of magnetic particles is possible due to at least partly saturation of the sensor device because of the high external magnetic field. Furthermore, when an electromagnet is used for applying the external magnetic field, extra magnetic noise may be introduced.

Another drawback is that when a permanent magnet is used for applying the external magnetic field, there is a need for mechanical means to remove the external magnetic field in case of a permanent magnet.

Therefore, according to a second embodiment of the invention which is illustrated in FIG. 14, the magnetic sensor device 20 comprises a first integrated magnetic field generating means 21 which may be formed by at least one integrated field generating current wire 21, the first magnetic field generating means 21 being for generating a first magnetic field in a first direction, the first magnetic field being for attracting magnetic or magnetizable objects to the surface of the magnetic sensor device. The magnetic sensor device 20 furthermore comprises at least one sensor element 24 oriented in a first direction. According to the second embodiment, the at least one integrated magnetic field generating means may be oriented in a second direction substantially perpendicular to the first direction in which the at least one sensor element 24 is oriented.

The second magnetic field generating means may, according to the second embodiment, be formed by an external magnetic field generating means (not shown in the drawings). The second magnetic field generating means generates a second magnetic field Hₑₓₜ in a second direction and having a second magnetic field strength.

According to embodiments of the invention, the magnetic sensor device 20 according to the second embodiment of the invention, may furthermore comprise a third magnetic field generating means 28, for example formed by two current wires 28a, 28b, for generating a third magnetic field for orienting dipolar magnetic fields generated by the magnetic moment of the magnetic particles 22 as explained hereinafter. A current flowing through the third magnetic field generating means 28 generates a third magnetic field which magnetizes the magnetic particles 22 present at the sensor surface 23. The magnetic particles 22 hereby develop a magnetic moment m. The magnetic moment m then generates dipolar magnetic fields, which have in-plane magnetic field components at the location of the sensor element 24. Thus, the magnetic particles 22 deflect the third magnetic field induced by the current through the third magnetic field generating means 28, resulting in the magnetic field component in the sensitive x-direction of the sensor element 24. According to these embodiments, the third magnetic field generating means 28 may be oriented in a same direction as the at least one sensor element 24 and thus in a direction substantially perpendicular to the direction in which the first magnetic field generating means 21 is oriented.

Hereinafter, the functioning of the device according to the second embodiment of the invention will be described.

First, a current is sent through the first magnetic field generating means 21, in the example given the integrated magnetic field generating wire 21, hereby generating a first magnetic field for attracting magnetic particles 22 to the sensor surface 23. The second magnetic field generating means, in the example given external magnetic field generating means, is, during the attracting step, switched off.

In the ‘attract’ phase the magnetic particles 22 are concentrated from the bulk of the sample fluid to a zone near the sensor surface 23. The time needed to attract the magnetic particles 22 toward the sensor surface 23 should preferably be as low as possible, e.g. lower than 30 minutes, preferably lower than 10 minutes, and more preferred lower than 1 minute.

At least some of the magnetic particles 22 which are attracted towards the sensor surface 23 may bind to binding sites present on the sensor surface 23. In the ‘bind’ phase, the magnetic particles 22 are brought even closer to the binding surface in a way to optimize the occurrence of desired (bio)chemical binding to a capture or binding area on the sensor surface 23, i.e. the area where there is a high detection sensitivity by the at least one sensor element 24, e.g. magnetic sensors, and a high biological specificity of binding. For optimizing the bind process, there is a need to increase the contact efficiency (to maximize the rate of specific biological binding when the bead is close to the binding surface) as well as the contact time (the total time that individual beads are in contact with the binding surface).

In a next step, a second magnetic field is generated by switching on the external magnetic field generating means or by approaching a permanent external magnet hereby generating a second magnetic field, on top of the presence of the first magnetic field. The magnetic field generated by the integrated field generating current wire 21 hereby serves for redirecting the applied external magnetic field such that the external magnetic field has a component oriented in a direction anti-parallel to the direction of the first magnetic field. This means that the external magnetic field is applied in a direction other than the sensitive x-direction of the GMR sensor element 24, and may thus be higher than what is possible according to the first embodiment of the invention. Most preferably, the external magnetic field is directed into the less-sensitive y-direction of the GMR sensor element 24. Because of the anti-parallel orientation of the first and second magnetic field, magnetic particles 22 will be repelled from the sensor surface 23.

According to the second embodiment, the combination of the external magnetic field and an internal magnetic field generated by a suitably chosen (amplitude and direction) current I₁ in at least one of the at least one integrated magnetic field generating means 21 which forms the first magnetic field generating means will repel magnetic particles 22 from the sensor surface 23.

According to embodiments of the invention, e.g. in the magnetic sensor device 20 according to the second embodiment which comprises a third magnetic field generating means 28, there may thus be three magnetic fields, i.e. a first magnetic field generated by the integrated magnetic field generating means 21 for attracting magnetic or magnetizable objects 22 to the sensor surface 23, a second magnetic field generated by the external magnetic field generating means which, in combination with the first magnetic field, generates a repelling force on the magnetic or magnetizable objects, and a third magnetic field generated by the third magnetic field generating means 28 and oriented substantially parallel to the sensor element for excitation and detection of the magnetic or magnetizable objects. Each individual magnetic field generating means generates a field and produces an attracting force when activated solely.

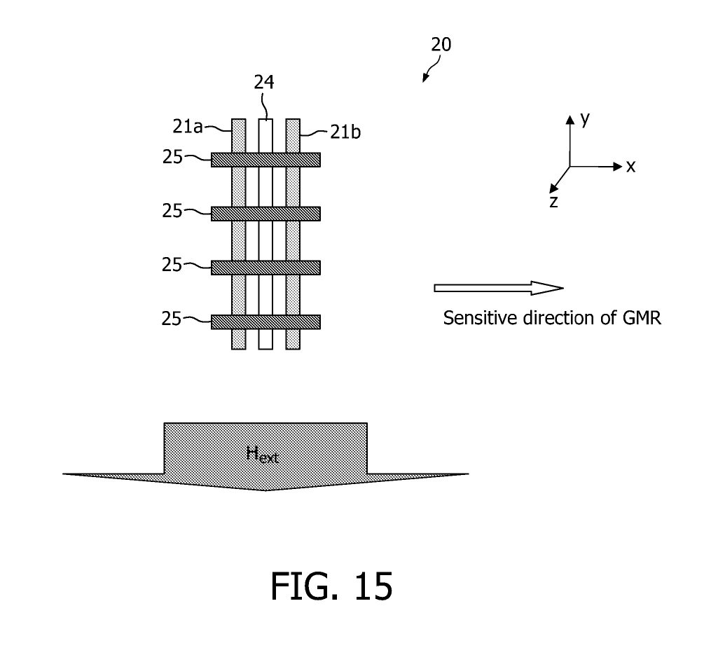

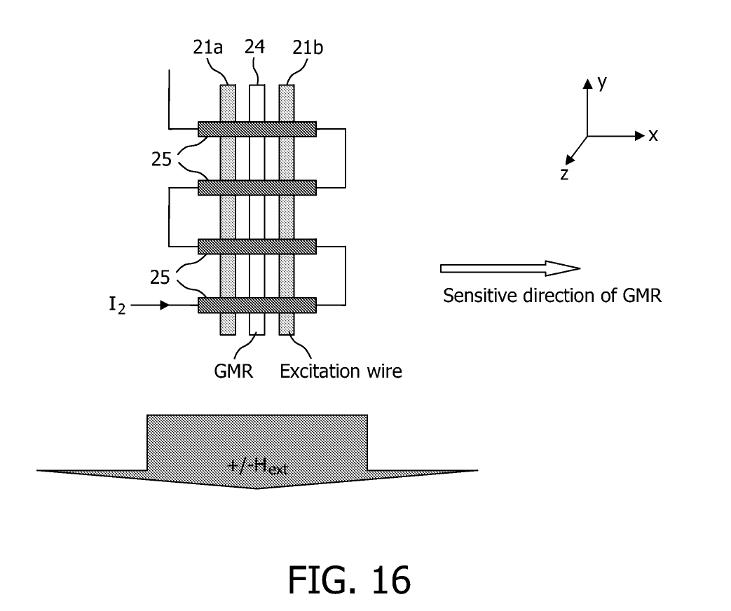

According to a third, more preferred embodiment of the present invention, the magnetic sensor device 20 may have a configuration which is comparable to the magnetic sensor device 20 according to the second embodiment and as illustrated in FIG. 14, i.e. it comprises an external magnetic field generating means and an integrated magnetic field generating device 25, as illustrated in FIGS. 15 and 16. However, contrary to the device according to the second embodiment of the invention, the integrated magnetic field generating means is now part of the second magnetic field generating means. The external magnetic field generating means may be a permanent magnet. The applied external magnetic field may have a magnitude of between 200 A/m and 20000 A/m.

It has to be noted that in all figures the lower left corner of the first field generating wire 21a forms the origin of the co-ordinate system indicated in the figures.

A magnetic sensor device 20 according to the third embodiment of the invention is illustrated in FIG. 15. The magnetic sensor device 20 comprises a first magnetic field generating means 21a, 21b which may be used for generating a first magnetic field for attracting magnetic particles 22 to the sensor surface 23. The first magnetic field generating means 21a, 21b is integrated in the sensor device 20. According to the example given in FIG. 15, the first integrated magnetic field generating means 21 may comprise a first and second current wire 21a, 21b respectively. This example is not limiting the invention, the first integrated magnetic field generating means 21 may also comprise only one current wire or may comprise more than two current wires. The invention will further be described by means of the first integrated magnetic field generating means comprising first and second current wires 21a, 21b but this is not intended to limit the invention.

By sending a first current through at least one of the current wires 21a, 21b a first magnetic field is generated. The first magnetic field has a magnetic field gradient because of which magnetic particles 22 may be attracted towards and onto the surface 23 of the magnetic sensor device 20.

Furthermore, the magnetic sensor device 20 according to the third embodiment of the invention comprises at least one GMR sensor element 24. Again, it has to be noted that the sensor element 24 may, according to other embodiments of the invention, be any sensor element that is suitable for detecting the presence and/or amount of magnetic particles 22 (see above). The GMR sensor element 24 may be used for detecting and/or quantifying magnetic particles 22 present at or near the sensor surface 23.

According to the third embodiment of the invention, the second magnetic field generating means may be formed by an external magnetic field generating means (not shown in the figure) in combination with at least one integrated magnetic field generating means 25, in the example given an integrated field generating current wire 25. The at least one integrated magnetic field generating means 25, in the example given an integrated field generating current wire 25, extends in a direction substantially perpendicular to the direction in which the current wires 21a, 21b and the at least one GMR sensor element 24 extend. According to the examples in FIGS. 15 and 16, the sensor device 20 may comprise a plurality of integrated magnetic field generating means 25. However, according to other embodiments, the sensor device 20 may comprise a single integrated magnetic field generating means 25.

The integrated field generating current wire 25 serves for redirecting the applied external magnetic field such that the combined magnetic field has a component oriented in a direction anti-parallel to the direction of the first magnetic field. This means that the external magnetic field is applied in a direction other than the sensitive x-direction of the GMR sensor element 24, and may thus be higher than what is possible according to the first embodiment of the invention. Most preferably, the external magnetic field is directed into the less-sensitive y-direction of the GMR sensor element 24.

The combination of the external magnetic field, which is redirected by the integrated field generating current wire 25 and has a first direction, and the internal magnetic field generated by the current wires 21a, 21b and having a second direction, the first and second direction being substantially anti-parallel to each other, will repel magnetic particles 22 from the sensor surface 23.

Because the external magnetic field is oriented along the less-sensitive y-direction of the GMR sensor element 24, and thus in a direction different from the sensitive x-direction of the GMR sensor element 24, the applied external magnetic field may be much larger compared to magnetic sensor devices 20 according to the first embodiment, i.e. may be between 200 A/m and 20000 A/m. As a consequence, much higher repulsive forces suitable for removing magnetic particles 22 from the sensor surface 23 can be obtained using the magnetic sensor device 20 according to the present invention.

The magnetic sensor device 20 according to the third embodiment of the invention may be used for combining measurements, i.e. determining and/or quantifying magnetic particles 22 in a sample fluid, with bond strength determination. For example, during determining and/or quantifying magnetic particles 22 in a sample fluid, repelling of magnetic particles 22 from the surface may be used to remove weakly or non-specific bond particles 22. In this case, a washing step is no longer necessary.

The magnetic sensor device 20 according to the third embodiment may also be used to perform bond strength determination without performing measurements for determining and/or quantifying magnetic particles 22 in a sample fluid. When no measurements, i.e. determining and/or quantifying magnetic particles 22 in a sample fluid, are performed during repelling magnetic particles 22 from the sensor surface 23, still higher external field strengths up to 10 kA/m may be allowed so that still higher repulsive forces may be generated. The latter may be useful when binding strength of magnetic particles 22 to a sensor surface 23 is to be determined because in that case, all magnetic particles 22, weakly as well as strongly bond, non-specific as well as specific bond particles 22, may have to be removed from the sensor surface 23.

Hereinafter, the principle of functioning of the magnetic sensor device 20 according to the third embodiment will be described.

By applying a current to the first current wire 21a, or to the current wires 21a, 21b, a first magnetic field is generated in a first direction. The generated first magnetic field has a strong field gradient through which magnetic particles 22 may be attracted to the sensor surface 23. The at least one second magnetic field generating means, in the example given the integrated field generating wire 25, is, during the attracting step, switched off or in other words, no current is sent through the field generating current wire 25.

In the ‘attract’ phase the magnetic particles 22 are concentrated from the bulk of the sample fluid to a zone near the sensor surface 23. The time needed to attract the magnetic particles 22 toward the sensor surface 23 should preferably be as low as possible, e.g. lower than 30 minutes, preferably lower than 10 minutes, and more preferred lower than 1 minute.

At least some of the magnetic particles 22 which are attracted towards the sensor surface 23 may bind to binding sites present on the sensor surface 23. In the ‘bind’ phase, the magnetic particles 22 are brought even closer to the binding surface in a way to optimize the occurrence of desired (bio)chemical binding to a capture or binding area on the sensor surface 23, i.e. the area where there is a high detection sensitivity by the at least one sensor element 24, e.g. magnetic sensors, and a high biological specificity of binding. For optimizing the bind process, there is a need to increase the contact efficiency (to maximize the rate of specific biological binding when the bead is close to the binding surface) as well as the contact time (the total time that individual beads are in contact with the binding surface).

In a next step, the external magnetic field is applied by switching on the external magnetic field generating means or by approaching a permanent external magnet, and at the same time a current is sent through the integrated part of the second field generating means, in the example given the integrated field generating current wire 25, for generating a second magnetic field in a second direction. In other words, in this step, the second field generating means, in the example given the integrated field generating current wire 25, is also switched on. The combined magnetic field from the first and the second magnetic field generating means, the second magnetic field generating means comprising an external magnetic field generating means and an integrated magnetic field generating means will repel magnetic particles 22 from the sensor surface 23. The first current wire 21a stays on during this step.

Many operation or functioning possibilities are possible for the magnetic sensor device 20 according to the third embodiment. For example, simultaneous activation of the additional integrated magnetic field generating means 25 or time-multiplexed operation by activating one or more of the integrated magnetic field generating means 25 during a pre-determined time slot may be possible.

According to embodiments of the invention, the integrated magnetic field generating means 25 may be connected to each other as illustrated in FIG. 16. In that case, the integrated magnetic field generating means 25 are all actuated at a same time, for example by sending a current I₂ through the integrated magnetic field generating means as shown in FIG. 16. By modulating the sign of the external magnetic field (invert/non-invert), magnetic particles are sequentially repelled by all integrated magnetic field generating means 25.

Because, as described above, repulsion only takes place above the excited current wires 21a, 21b, the device according to the second embodiment of the invention is suitable for multiplexing different assays on a same sensor device 20.

The above-described second and third embodiment have, however, the disadvantage that still an external magnetic field is required. Therefore, hereinafter, some embodiments will be described in which the magnetic sensor devices 20 do not require an external magnetic field.

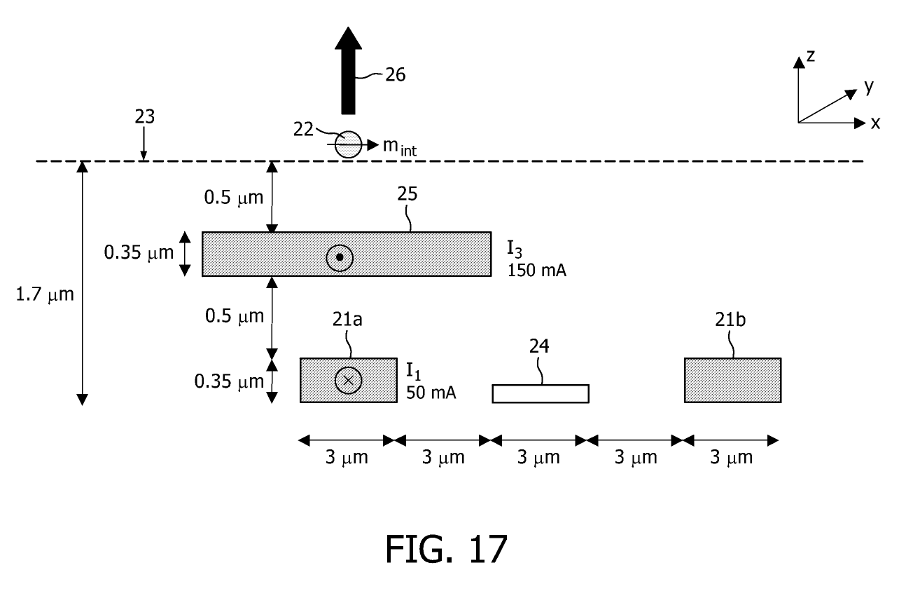

According to a fourth embodiment of the invention the magnetic sensor device 20 comprises a first integrated magnetic field generating means 21 and at least one magnetic sensor element such as e.g. a GMR sensor element 24. FIG. 17 illustrates an example of a magnetic sensor device 20 according to the fourth embodiment. In the example given, the first magnetic field generating means 21 may comprise a first and second current wire 21a, 21b, and one GMR sensor element 24 located in between the first and second current wires 21a, 21b. It has to be understood that this is only an example of a possible implementation of the magnetic sensor device 20 according to the fourth embodiment of the invention and that other implementations are also disclosed. For example, the magnetic sensor device 20 may comprise more or less than two current wires 21a, 21b and/or may comprise more than one GMR sensor element 24 or may comprise other sensor elements 24 than a GMR sensor element (see above).

According to the fourth embodiment of the present invention, the second magnetic field generating means may only comprise an integrated magnetic field generating means, no external magnetic field generating means, in the example given and illustrated in FIG. 17, an integrated field generating current wire 25 which is located in between the first current wire 21a and the surface 23 of the magnetic sensor device 20. The integrated field generating current wire 25 may extend in a direction substantially parallel to the direction in which the current wires 21a, 21b and the GMR sensor element 24 extend. According to other embodiments, the integrated field generating means 25 may comprise two or more field generating current wires 25. For example, the magnetic sensor device 20 may comprise a first field generating current wire 25 in between the first current wire 21a and the sensor surface 23 (as in FIG. 17) and may comprise a second field generating current wire 25 in between the second current wire 21b and the sensor surface 23. According to still other embodiments of the invention, the magnetic sensor device 20 may comprise one field generating current wire 25 extending over the complete sensor device 20 in the x-direction, i.e. extending from in between the first current wire 21a and the sensor surface 23 to in between the second current wire 21b and the sensor surface 23. The field generating current wire 25 may preferably have a length comparable to the length of the first and second current wires 21a, 21b, because a repelling force only occurs at locations where both a current wire 21a or 21b and a field generating current wire 25 are present. However, according to other, less preferred embodiments of the invention, the field generating current wire 25 may have a length shorter or longer than the length of the first and second current wire 21a, 21b.

The principle of the functioning of the magnetic sensor device 20 according to the fourth embodiment of the present invention will be described hereinafter using the example given in FIG. 17.

By applying a current to the first current wire 21a, a first magnetic field is generated in a first direction. The generated first magnetic field has a strong field gradient through which magnetic particles 22 may be attracted to the sensor surface 23. According to the example given in FIG. 17, a current of about 50 mA is sent through the first current wire 21 in a direction going into the plane of the paper. The second magnetic field generating means, in the example given the integrated field generating wire 25, is, during the attracting step, switched off or in other words, no current is sent through the field generating current wire 25.

In the ‘attract’ phase the magnetic particles 22 are concentrated from the bulk of the sample fluid to a zone at or near the sensor surface 23. The time needed to attract the magnetic particles 22 toward the binding surface 23 should preferably be as low as possible, e.g. lower than 30 minutes, preferably lower than 10 minutes, and more preferred lower than 1 minute.

At least some of the magnetic particles 25 which are attracted towards the sensor surface 23 may bind to binding sites present on the sensor surface 23. In the ‘bind’ phase, the magnetic particles 25 are brought even closer to the binding surface in a way to optimize the occurrence of desired (bio)chemical binding to a capture or binding area on the sensor surface 23, i.e. the area where there is a high detection sensitivity by the at least one sensor element 24, e.g. magnetic sensors, and a high biological specificity of binding. For optimizing the bind process, there is a need to increase the contact efficiency (to maximize the rate of specific biological binding when the bead is close to the binding surface) as well as the contact time (the total time that individual beads are in contact with the binding surface).

In a next step, a current is sent through the second field generating means, in the example given the integrated field generating current wire 25, for generating a second magnetic field in a second direction. In other words, in this step, the second field generating means, in the example given the integrated field generating current wire 25, is switched on. The first current wire 21a stays on during this step. According to the present invention, the current sent through the field generating current wire 25 is such that the first magnetic field has a direction substantially anti-parallel to the direction of the second magnetic field. With substantially anti-parallel is meant that the first and second magnetic field may enclose an angle of less than 10°, preferably less than 5° and most preferably less than 1°. According to the example given in FIG. 17, a current of about 150 mA is sent through the field generating wire 25 in a direction coming out of the plane of the paper, and thus in the opposite direction as the current sent through the first current wire 21a. According to the fourth embodiment of the invention, preferably the second magnetic field generated by the second magnetic field generating means, in the example given the integrated field generating current wire 25, is larger than the first magnetic field generated by the first current wire 21a such that the result is a repelling force, indicated by reference number 26 in FIG. 17. The anti-parallel orientation of the first and second magnetic field creates a field minimum above the current wire 21a. Therefore, the total field gradient is oriented away from the current wire 21a. Thus, a magnetic particle 22 located in the fluid sample in the vicinity of the current wire 21a, or in other words, at the sensor surface 23 above the current wire 21a (as illustrated in FIG. 17), experiences a force away from the sensor surface 23 and is thus pulled into the fluid.

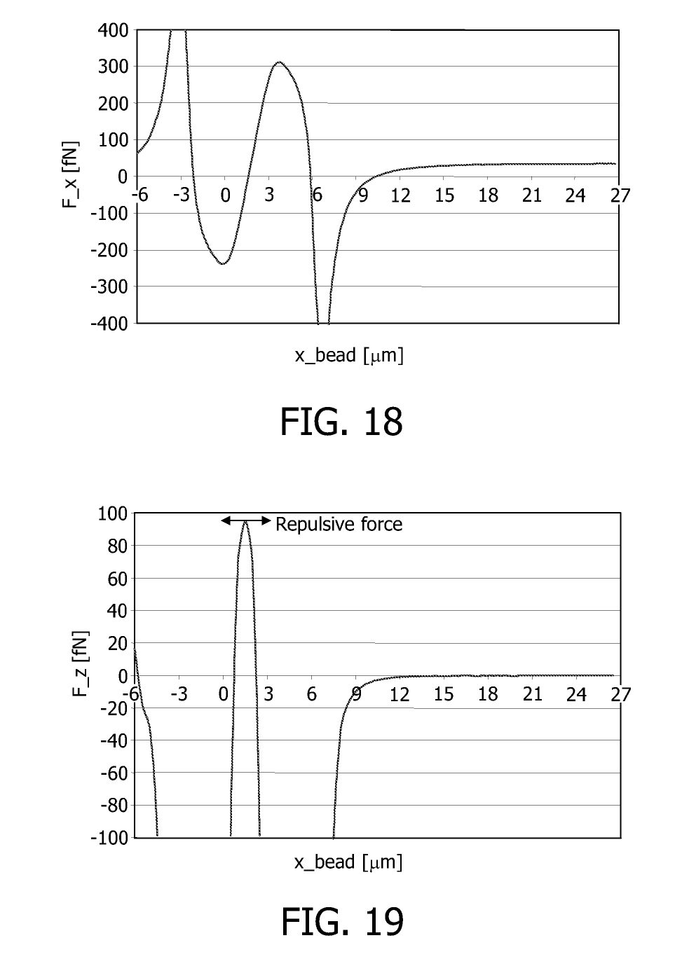

FIGS. 18 and 19 respectively illustrate the horizontal and vertical magnetic forces at the sensor surface 23 as a function of the x-position of the magnetic particles 22 at z=1.7 μm (see FIG. 17), for an excitation current of 50 mA and a current through the second magnetic field generating means of 150 mA in case of 300 nm Ademtech beads. It can be seen from FIG. 19 that the repulsive force is the biggest at the sensor surface 23 above the first current wire 21a, and is thus located at the position at the sensor surface 23 where magnetic particles 23 were attracted to in the previous step. The repulsive force is between 95 and 100 fN, which may be sufficient to remove non-specific bonded particles 22 from the sensor surface 23.

It has, however, to be noted that a rather big current of about 150 mA is required. A disadvantage of this is that a rather big heat dissipation can occur. In the configuration discussed above and illustrated in FIG. 17 a continuous dissipation of 100 mW occurs. This may, however, be reduced by applying pulsed actuation to the integrated field generating current wire 25. Another way for avoiding the above mentioned disadvantage is to divide the integrated field generating current wire 25 in subsequent actuated sub-wires, which limits the power dissipation.

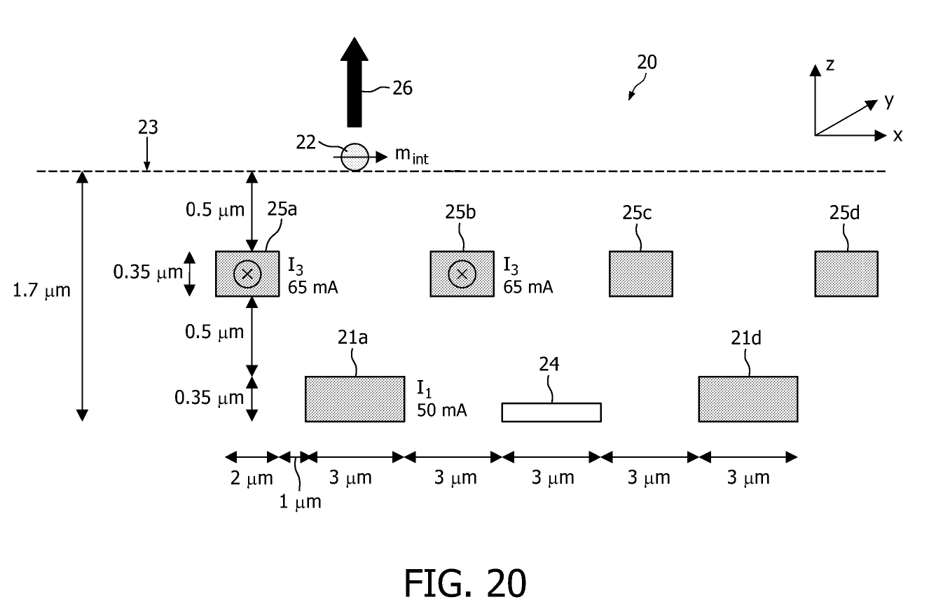

It has furthermore to be remarked that, the larger the magnetic particles 22 are, the larger the repelling force will be on the magnetic particle 22 for a same magnetic field. According to a most preferred, fifth embodiment of the present invention, the second magnetic field generating means may comprise a plurality of integrated small current wires 25a-25d. This is illustrated in FIG. 20. The plurality of integrated small current wires 25a-25d may be located in between the sensor surface 23 and the first current wire 21a, the GMR sensor element 24 and the second current wire 21b. The plurality of integrated small current wires 25a-25d may all have a same size or may have different sizes. Preferably, the plurality of integrated small current wires 25a-25d may have a width of between 1 μm and 5 μm and preferably may have a width of about 2 μm. Preferably, the plurality of integrated small current wires may be located symmetrically above the first and second current wires 21a, 21b with respect. This can be seen from FIG. 20. The integrated small current wires 25a, 25b are symmetrically located at each side of the current wire 21a while the integrated small current wires 25c, 25d are symmetrically located at each side of the current wire 21b.

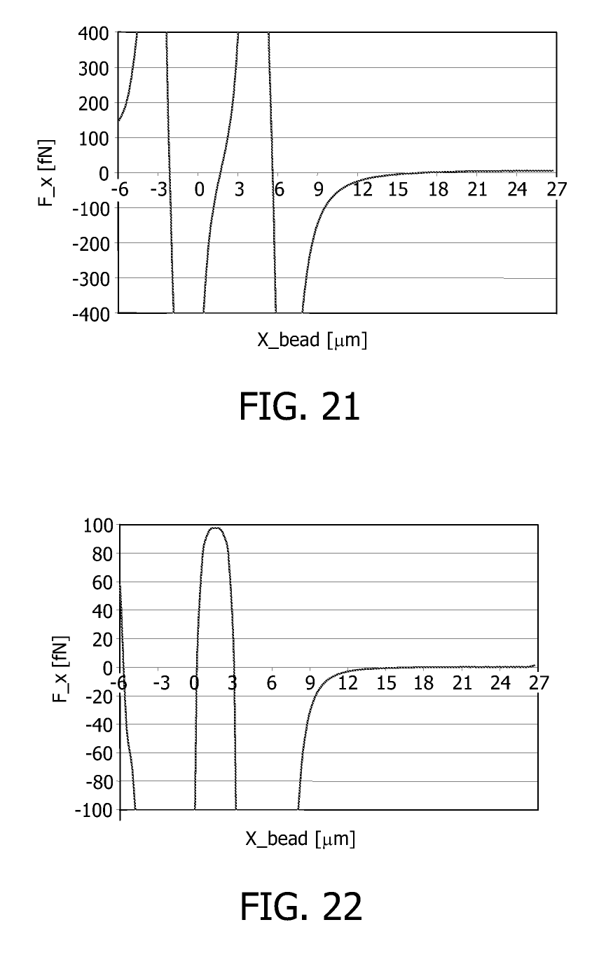

FIGS. 21 and 22 respectively illustrate the horizontal and vertical forces at the sensor surface 23 as a function of the x-position of the magnetic particles 22 at z=1.7 μm (see FIG. 20), for an excitation current of 50 mA in current wire 21a and for a current of 65 mA in current wires 25a and 25b in case of 300 nm Ademtech beads. It can be seen that the repelling force (indicated by reference number 26 in FIG. 20) is located above the current wire 21a at the sensor surface 23.

The principle of functioning of the magnetic sensor device 20 according to the fifth embodiment is similar to that of the magnetic sensor device 20 according to the fourth embodiment. In the device 20 according to the fifth embodiment, the magnetic fields generated by the current wires 25a, 25b amplify each other and therefore, they do not have to be very large which leads to a lower heat dissipation than when larger current wires have to be used.

The magnetic sensor device 20 according to embodiments of the present invention as described above may, compared to conventional external field generators outside the sensor chip/cartridge, have some advantages:

Permanent static magnetic field, thus power effective.

Well-defined and controllable (in amplitude and position) repelling forces, which is excellent for, for example, multiplex purposes.

Minimal mechanical adjustment needed between the sensor device and a read-out station, only a driving means needs to be provided which is adapted for controlling the switching on and switching off of the first and second magnetic field generating means.

The magnetic sensor device 20 according to embodiments of the present invention may be used for determining the strength of a binding between a magnetic particle 22 and a sensor surface 23.

The magnetic sensor device 20 according to embodiments of the present invention may be used for distinguishing between weak and strong bonds, or between specific and non-specific bonds, during measurements for determining and/or quantifying target molecules in a sample fluid. In this case, a washing step as known by persons skilled in the art, may not be necessary.

Depending on the application and the repelling force needed, either a magnetic sensor device 20 according to the first, second, third or fourth embodiment may be used.

It has to be noted that in the above-described embodiments, DC magnetic fields are assumed. However, the present invention can also be implemented with varying, e.g. AC magnetic fields. When AC magnetic fields with a same frequency are generated by the first magnetic field generating means and by the integrated magnetic field generating means of the second magnetic field generating means, the current direction in both magnetic field generating means may be changed or modulated by changing the phase relation between both.

In a further aspect, the present invention also provides a method for attracting and repelling magnetic particles 22 to and from a sensor surface 23 using the magnetic sensor device as described in the embodiments above. The method comprises in a first step switching on the first, integrated magnetic field generating means 21, hereby generating a first magnetic field for attracting magnetic particles 22 to the sensor surface 23. Hereby, at least some of the attracted magnetizable objects may in this step bind to the sensor surface 23. In a next step, while the first magnetic field generating means 21 is still on, the second magnetic field generating means is switched on, hereby generating a second magnetic field for repelling magnetic particles 22 having a bonding strength below a predetermined value from the sensor surface 23. According to the present invention, generating the first and second magnetic field is such that the first magnetic field has a first direction and the second magnetic field has a second direction, the first and second direction being substantially anti-parallel to each other. With substantially anti-parallel is meant that the first and second direction of the first and second magnetic field may enclose an angle of less than 10°, preferably less than 5° and most preferred less than 1°.

When, for example, the magnetic sensor device 20 and method according to embodiments of the present invention, are used for combining measurement and distinguishing between weak and strong bonds between magnetic particles 22 and the sensor surface 23, the pre-determined value may be determined to be a value corresponding with the binding strength of the weakly bond particles 22. Hence, bonds between magnetic particles 22 and the sensor surface 23 which have a strength higher than the predetermined value, will not be removed from the surface, those who have a binding strength lower than the predetermined value will, during the repelling step, be removed from the sensor surface 23.

When, according to other embodiments of the invention, the magnetic sensor device 20 and method according to embodiments of the invention are used for determining the strength of a binding between a magnetic particle 22 and a sensor surface 23, the predetermined value may be much higher than in the above-described example, because according to the present embodiments, all magnetic particles 22, weakly and strongly bond, will have to be removed from the sensor surface 23.

Another example of the use of the magnetic sensor device 20 and method according to embodiments of the invention will be described hereinafter. The repelling force for removing magnetic particles 22 from the sensor surface 23 may be modulated by modulating the strength of the magnetic field generated by the second magnetic field generating means, for example by modulating the current in the integrated field generating means 25. When applying a weak second magnetic field, only weakly bonded magnetic particles 22 may be removed from the sensor surface 23. By increasing the strength of the second magnetic field, stronger bonded magnetic particles 22 may be removed from the sensor surface 23 as well. The strength of the magnetic field may be further increased until all magnetic particles 22 are removed from the sensor surface 23. In that way, a scan may be made of all magnetic particle 22/sensor surface 23 bonds.

Because of the above, it is clear that the predetermined value of the binding strength depends on the application the magnetic sensor device 20 and method according to embodiments of the invention are used for. Furthermore, the predetermined value of the binding strength depends on the target moieties to be determined and on the ligands on the sensor surface 23 used to specifically bind target moieties.

Examples of binding strengths between receptors bond on magnetic particles and ligand molecules on a surface may be found in “Dissociation of Ligand-Receptor Complexes using Magnetic Tweezers” by C. Danilowcicz et al. For, for example, superparamagnetic particles functionalized with the receptor protein streptavidin in contact with a biotin ligand on a surface, a force of about 45 pico Newton (pN) is required for breaking the streptavidin-biotin bonds. Furthermore, for removing non-specifically bond magnetic particles, only low forces of about 5 to 10 pN are required in case of the above described example.

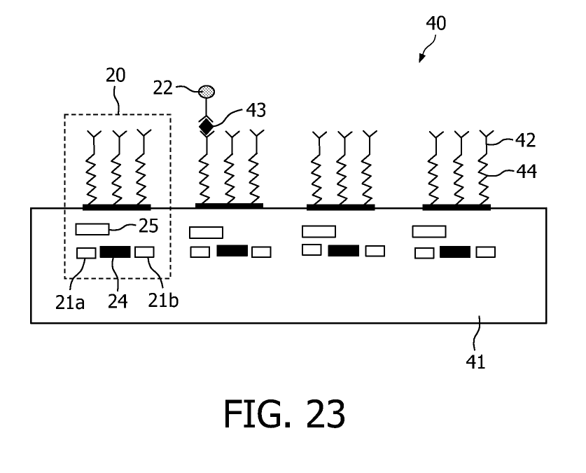

In another aspect, the present invention also provides a biochip 40 comprising at least one magnetic sensor device 20 according to embodiments of the present invention. FIG. 23 illustrates a biochip 40 according to an embodiment of the present invention. The biochip 40 may comprise at least one magnetic sensor device 20 according to embodiments of the present invention integrated in a substrate 41. The term “substrate” may include any underlying material or materials that may be used, or upon which a device, a circuit or an epitaxial layer may be formed. The term “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include, for example, an insulating layer such as a SiO₂ or an Si₃N₄ layer in addition to a semiconductor substrate portion. Thus the term “substrate” also includes glass, plastic, ceramic, silicon-on-glass, silicon-on-sapphire substrates. The term “substrate” is thus used to define generally the elements for layers that underlie a layer or portions of interest. Also the “substrate” may be any other base on which a layer is formed, for example a glass or metal layer.

According to embodiments of the invention a single magnetic sensor device 20 or a multiple of magnetic sensor devices 20 may be integrated on the same substrate 41 to form the biochip 40.

According to the present example, the first magnetic field generating means 21 may comprise a first and a second electrical conductor, e.g. implemented by a first and second current conducting wire 21a and 21b. Also other means instead of current conducting wires 21a, 21b may be applied to generate the first magnetic field. Furthermore, the first magnetic field generating means 21 may also comprise another number of electrical conductors.

In each magnetic sensor device 20 at least one sensor element 24, for example a GMR element, may be integrated in the substrate 41 to read out the information gathered by the biochip 40, thus for example to read out the presence or absence of target particles 43 via magnetic or magnetizable objects 22, e.g. magnetic nanoparticles, attached to the target particles 43, thereby determining or estimating an areal density of the target particles 43. The magnetic or magnetizable objects 22, e.g. magnetic particles, are preferably implemented by so called superparamagnetic beads. Binding sites 42 which are able to selectively bind a target molecule 43 are attached on a probe element 44. The probe element 44 is attached on top of the substrate 41.

According to the present invention, each magnetic sensor device 20 comprises a second magnetic field generating means. According to the example given in FIG. 23, the second magnetic field may comprise an integrated field generating means 25, in the example given an integrated field generating current wire 25.

The functioning of the biochip 40, and thus also of the magnetic sensor device 20, will be explained hereinafter. Each probe element 44 may be provided with binding sites 42 of a certain type, for binding pre-determined target molecules 43. A target sample, comprising target molecules 43 to be detected, may be presented to or passed over the probe elements 44 of the biochip 40, and if the binding sites 42 and the target molecules 43 match, they bind to each other. The superparamagnetic beads 22, or more generally the magnetic or magnetizable objects, may be directly or indirectly coupled to the target molecules 43. The magnetic or magnetizable objects, e.g. superparamagnetic beads 22, allow to read out the information gathered by the biochip 40.

In addition to molecular assays, also larger moieties can be detected, e.g. cells, viruses, or fractions of cells or viruses, tissue extract, etc. Detection can occur with or without scanning of the sensor element 24 with respect to the biosensor surface 23.

Measurement data can be derived as an end-point measurement, as well as by recording signals kinetically or intermittently.

The magnetic or magnetizable objects 22, e.g. magnetic particles, can be detected directly by the sensing method. As well, the magnetic or magnetizable objects 22, e.g. magnetic particles, can be further processed prior to detection. An example of further processing is that materials are added or that the (bio)chemical or physical properties of the magnetic or magnetizable objects 22, e.g. magnetic particles, are modified to facilitate detection.

The magnetic sensor device 20, biochip and method according to embodiments of the present invention can be used with several biochemical assay types, e.g. binding/unbinding assay, sandwich assay, competition assay, displacement assay, enzymatic assay, etc.

The magnetic sensor device 20, biochip and method according to embodiments of this invention are suitable for sensor multiplexing (i.e. the parallel use of different sensors and sensor surfaces), label multiplexing (i.e. the parallel use of different types of labels or magnetic or magnetizable objects) and chamber multiplexing (i.e. the parallel use of different reaction chambers).

The magnetic sensor device 20, biochip and method according to embodiments of the present invention can be used as rapid, robust, and easy to use point-of-care biosensors for small sample volumes. The reaction chamber can be a disposable item to be used with a compact reader, containing the one or more magnetic field generating means and one or more detection means. Also, the device, methods and systems of the present invention can be used in automated high-throughput testing. In this case, the reaction chamber may, for example, be a well plate or cuvette, fitting into an automated instrument.

It is to be understood that although preferred embodiments, specific constructions and configurations, as well as materials, have been discussed herein for devices according to the present invention, various changes or modifications in form and detail may be made without departing from the scope and spirit of this invention.

1. A magnetic sensor device (20) having a surface (23) and comprising:
a first integrated magnetic field generating means (21) for generating a first magnetic field in a first direction and having a first magnetic field strength, the first magnetic field being for attracting magnetic or magnetizable objects (22) to the surface (23) of the magnetic sensor device (20),
at least one sensor element (24),
a second magnetic field generating means for generating a second magnetic field in a second direction and having a second magnetic field strength, the second magnetic field in combination with the first magnetic field being for repelling magnetic or magnetizable objects (22) having a binding strength below a predetermined value from the surface (23) of the magnetic sensor device (20), the first and second direction being substantially anti-parallel to each other, and
driving means for controlling modulation of the first and second magnetic field strengths.

2. A magnetic sensor device (20) according to claim 1, wherein the second magnetic field generating means comprises an external magnetic field generating means.

3. A magnetic sensor device (20) according to claim 1, wherein the second magnetic field generating means comprises at least an integrated magnetic field generating means (25).

4. A magnetic sensor device according to claim 1, wherein the driving means for controlling modulation of the first and second magnetic field strength is driving means for controlling switching on and switching off of the first integrated magnetic field generating means (21) and the second magnetic field generating means.

5. A magnetic sensor device (20) according to claim 2, wherein the second magnetic field generating means furthermore comprises at least one integrated magnetic field generating means (25).

6. A magnetic sensor device (20) according to claim 5, the at least one sensor element (24) and the first integrated magnetic field generating means extending in a first direction, wherein the at least one integrated magnetic field generating means (25) of the second magnetic field generating means is oriented in a second direction substantially perpendicular to the first direction.

7. A magnetic sensor device (20) according to claim 3, wherein the at least one integrated magnetic field generating means (25) of the second magnetic field generating means is a current wire.

8. (canceled)

9. A magnetic sensor device (20) according to claim 2, wherein the generated external magnetic field has a magnitude between 200 A/m and 20000 A/m.

10. A magnetic sensor device (20) according to claim 3, wherein the at least one integrated magnetic field generating means (25) of the second magnetic field generating means is oriented in a direction substantially parallel to the first integrated magnetic field generating means (21) and to the at least one sensor element (24).

11. A magnetic sensor device (20) according to claim 1, wherein the second magnetic field generating means comprises a plurality of current wires (25a-25d).

12. A magnetic sensor device (20) according to claim 3, wherein the at least one integrated magnetic field generating means (25) of the second magnetic field generating means is located in between the sensor surface (23) and the first integrated magnetic field generating means (21).

13. A magnetic sensor device (20) according to claim 1, wherein the first magnetic field generating means (21) comprises at least one current wire.

14. A magnetic sensor device (20) according to claim 2, the at least one sensor element (24) extending in a first direction, wherein the first magnetic field generating means (21) comprises an integrated magnetic field generating means oriented in a second direction substantially perpendicular to the first direction.

15. A magnetic sensor device (20) according to claim 1, wherein the magnetic sensor device (20) comprises third magnetic field generating means (28) for generating a third magnetic field, the third magnetic field being for orienting dipolar magnetic fields generated by magnetic moments of magnetic or magnetizable objects (22) in a sensitive direction of the at least one sensor element (24).

16. A magnetic sensor device (20) according to claim 1, wherein the at least one sensor element (24) is selected from the group consisting of: a GMR sensor element, a TMR sensor element, an AMR sensor element, a Hall sensor.

17. A biochip comprising at least one magnetic sensor device (20) according to claim 1.

18. The use of the magnetic sensor device (20) according to claim 1 in biological or chemical sample analysis.

19. The use of the biochip according to claim 17 in biological or chemical sample analysis.

20. Method for attracting and repelling magnetic or magnetizable objects (22) from a sensor surface (23) of a sensor device (20), the method comprising:
modulating a first magnetic field strength of a first magnetic field generated by a first magnetic field generating means (21), the first magnetic field being for attracting magnetic or magnetizable objects (22) to the sensor surface (23), at least some of the attracted magnetic or magnetizable objects (22) hereby being given a possibility to bind to the sensor surface (23), and
modulating a second field strength of a second magnetic field generated by a second magnetic field generating means, the second magnetic field, in combination with the first magnetic field, being for repelling from the sensor surface (23) magnetic or magnetizable objects (22) having a bonding strength below a predetermined value,
wherein the first and second magnetic field are generated such that the first magnetic field has a first direction and the second magnetic field has a second direction, the first and second direction being substantially anti-parallel to each other.

21. Method according to claim 20, wherein modulating the first and second magnetic field strength is performed by:
switching on the first integrated magnetic field generating means (21) for generating a first magnetic field for attracting magnetic or magnetizable objects (22) to the sensor surface (23), and
switching on the second magnetic field generating means for generating a second magnetic field for, in combination with the first magnetic field, repelling from the sensor surface (23) magnetic or magnetizable objects (22) having a bonding strength below a predetermined value.

22. (canceled)

23. (canceled)

24. (canceled)
